(19) United States
(12) Patent Application Publication
(10) Pub. No.: US 2026/0354038 A1
(43) Pub. Date: Nov. 5, 2026

(54) FABRICATION METHOD FOR ELECTRIC CIRCUIT DEVICE, AND QUBIT DEVICE

(71) Applicant: RIKEN, Saitama (JP)

(72) Inventors: Alexander BADRUTDINOV, Saitama (JP); Rui LI, Saitama (JP); Yasunobu NAKAMURA, Saitama (JP)

(21) Appl. No.: 19/714,575

(22) Filed: Jun. 21, 2026

Related U.S. Application Data
(63) Continuation-in-part of application No. PCT/JP2023/046278, filed on Dec. 22, 2023.

(51) Int. Cl. H10N 60/01; G06N 10/40; H10N 60/82

(52) U.S. Cl. CPC H10N 60/0912; G06N 10/40; H10N 60/82

(57) ABSTRACT

Provided is a fabrication method for an electric circuit device, the fabrication method including forming a conductive layer on a substrate, forming a bottom resist layer on the conductive layer, forming a cover layer on the bottom resist layer, forming a top resist layer on the cover layer, forming a contact hole in the substrate by using the top resist layer as a mask, forming a first undercut structure by etching the bottom resist layer below the cover layer, and forming a contact metal layer on a sidewall of the contact hole and above a front surface of the substrate after the first undercut structure is formed.

The contents of the following patent application(s) are incorporated herein by reference: NO. PCT/JP2023/046278 filed in WO on Dec. 22, 2023.

### BACKGROUND

### 1. Technical Field

The present invention relates to a fabrication method for an electric circuit device, and a qubit device.

### 2. Related Art

Patent document 1 discloses a planar quantum device in which a through-silicon via is formed.

### RELATED ART DOCUMENTS

### Patent Documents

Patent Document 1: Specification of U.S. Pat. No. 11,088,310

Patent Document 2: Japanese Patent No. 7133842

Patent Document 3: Specification of U.S. Pat. No. 11,276,727

### BRIEF DESCRIPTION OF THE DRAWINGS

FIG. 1A illustrates an example of a cross sectional view of an electric circuit device 100.

FIG. 1B is a cross sectional view of a variation of the electric circuit device 100.

FIG. 1C illustrates an example of a top view of the electric circuit device 100.

FIG. 2 schematically illustrates a qubit device 200.

FIG. 3 illustrates an outline of a configuration of the qubit device 200.

FIG. 4A is a diagram for describing a fabrication method for the electric circuit device 100.

FIG. 4B is a diagram for describing the fabrication method for the electric circuit device 100.

FIG. 4C is a diagram for describing the fabrication method for the electric circuit device 100.

FIG. 4D is a diagram for describing the fabrication method for the electric circuit device 100.

FIG. 4E is a diagram for describing the fabrication method for the electric circuit device 100.

FIG. 4F is a diagram for describing the fabrication method for the electric circuit device 100.

FIG. 4G is a diagram for describing the fabrication method for the electric circuit device 100.

FIG. 4H is a diagram for describing the fabrication method for the electric circuit device 100.

FIG. 4I is a diagram for describing the fabrication method for the electric circuit device 100.

FIG. 5A is an example of an enlarged view of an area near a contact hole 70.

FIG. 5B is an example of the enlarged view of the area near the contact hole 70.

FIG. 5C is an example of the enlarged view of the area near the contact hole 70.

FIG. 6 illustrates an example of a relaxation time T₁ of the qubit device 200.

FIG. 7 illustrates an experimental result of the relaxation time T1.

### DESCRIPTION OF EXEMPLARY EMBODIMENTS

Hereinafter, the present invention will be described through embodiments of the invention, but the following embodiments do not limit the invention according to claims. In addition, not all of the combinations of features described in the embodiments are essential to the solution of the invention.

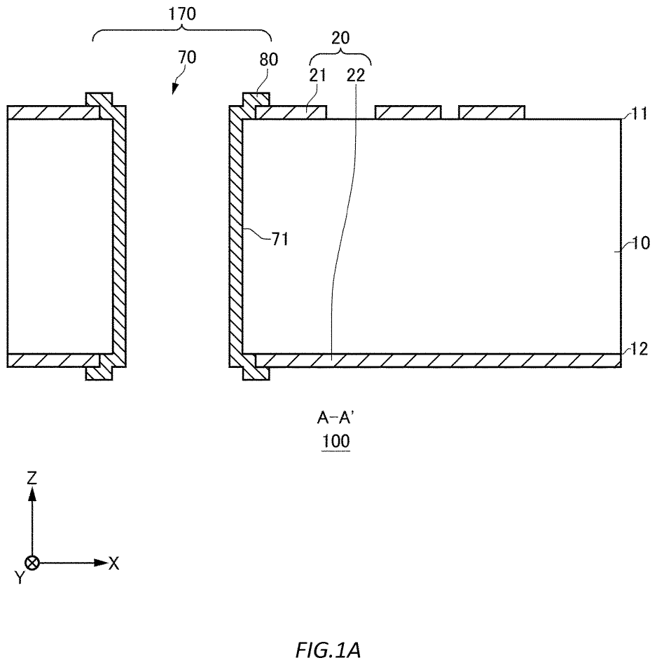

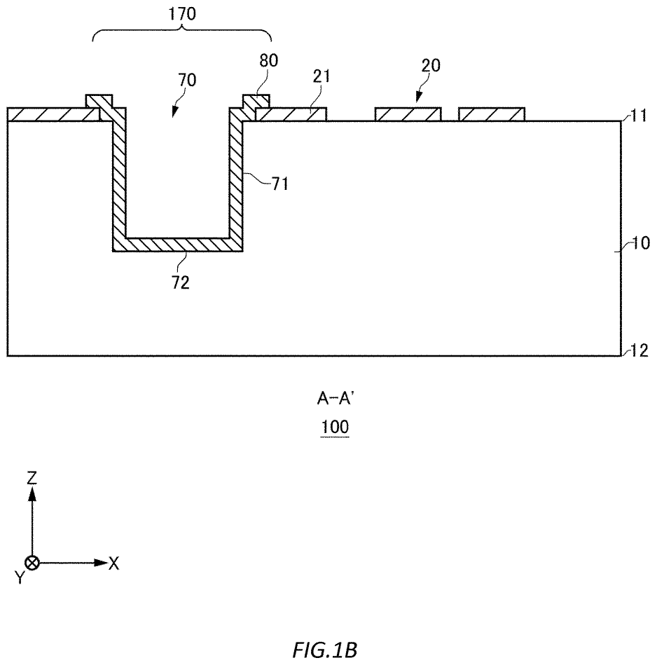

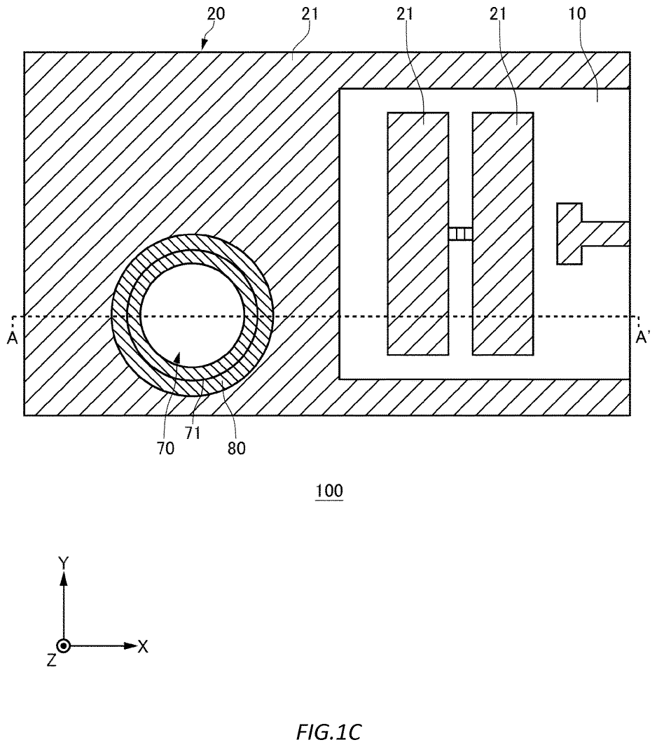

FIG. 1A illustrates an example of a cross sectional view of an electric circuit device 100. The electric circuit device 100 includes a substrate 10, a conductive layer 20, and a connection structure 170. The connection structure 170 has a contact hole 70 and a contact metal layer 80. The electric circuit device 100 may be a lateral device having the contact hole 70.

Herein, the electric circuit device 100 may be described using orthogonal coordinate axes of an X axis, a Y axis, and a Z axis. Herein, a plane parallel to an upper surface of the substrate 10 is set as an XY plane, and a depth direction of the substrate 10 is set as the Z axis. Note that a positive side in a Z axis direction is referred to as “up”, and a negative side in the Z axis direction is referred to as “down”. Herein, “up”, “down”, “front”, and “back” directions are not limited to a gravity direction or an installation direction during mounting of the electric circuit device 100.

The substrate 10 may be a dielectric substrate of silicon or the like. The substrate 10 may be another material such as a compound semiconductor. The substrate 10 of the present example has the contact hole 70 penetrating from a front surface 11 to a back surface 12. A configuration may be adopted in which the contact hole 70 does not completely penetrate through the substrate 10. The substrate 10 may have a plurality of contact holes 70.

The conductive layer 20 is provided on the substrate 10. The conductive layer 20 may be formed of a superconductive material and constitute a superconducting circuit. The conductive layer 20 may have a front surface conductive layer 21 and a back surface conductive layer 22. The front surface conductive layer 21 is formed on the front surface 11 of the substrate 10. The back surface conductive layer 22 is formed on the back surface 12 of the substrate 10. By using a fabrication method described later, the conductive layer 20 can be formed at a uniform thickness while contamination is reduced.

The connection structure 170 has the contact metal layer 80 formed in the contact hole 70, and is electrically connected to a conductive section such as the conductive layer 20. The connection structure 170 may be a through electrode such as a through-silicon via (TSV). The connection structure 170 may be electrically connected to the front surface conductive layer 21 and the back surface conductive layer 22. The connection structure 170 may be used to electrically connect a signal contact probe provided on a back surface 12 side of the substrate 10 and the front surface conductive layer 21.

The contact metal layer 80 is provided on a sidewall 71 of the contact hole 70 and the front surface 11 of the substrate 10. A material of the contact metal layer 80 may be the same as or different from the material of the conductive layer 20. The contact metal layer 80 may contain at least one of aluminum, tantalum, niobium, niobium nitride, titanium, titanium nitride, copper, gold, silver or tungsten. The contact metal layer 80 may extend along the substrate 10 from the sidewall 71 to the conductive layer 20. The contact metal layer 80 of the sidewall 71 may be integrally formed with the contact metal layer 80 of the front surface 11 by being formed at the same time. By using a fabrication method described later, the contact metal layer 80 can be formed while the contamination is reduced.

FIG. 1B is a cross sectional view of a variation of the electric circuit device 100. The electric circuit device 100 of the present example is different from the electric circuit device 100 of FIG. 1A in that the contact hole 70 does not penetrate through the substrate 10. In the present example, the difference from the electric circuit device 100 of FIG. 1A will be described in particular, and other aspects may be the same as the electric circuit device 100 of FIG. 1A.

The contact hole 70 extends from the front surface 11 in the depth direction of the substrate 10 but terminates without reaching the back surface 12. The contact hole 70 of the present example has a bottom surface 72. The electric circuit device 100 of the present example may include only the front surface conductive layer 21 as the conductive layer 20, and does not necessarily need to include the back surface conductive layer 22.

The contact metal layer 80 is provided on the sidewall 71 and the bottom surface 72 of the contact hole 70 and the front surface 11 of the substrate 10. The contact metal layer 80 may be formed on the sidewall 71, the bottom surface 72, and the front surface 11. The contact metal layer 80 may extend along the front surface 11 from the sidewall 71 until reaching to be in contact with the front surface conductive layer 21.

FIG. 1C illustrates an example of a top view of the electric circuit device 100. A cross section A-A′ of the present example may be a cross section of FIG. 1A or FIG. 1B. The contact metal layer 80 is provided to extend from the sidewall 71 to the front surface conductive layer 21. The front surface conductive layer 21 may be patterned to constitute a predetermined electric circuit. The electric circuit device 100 may be a qubit device, may be a semiconductor device of silicon, a compound semiconductor, or the like, or may be other devices such as micro electro mechanical systems (MEMS).

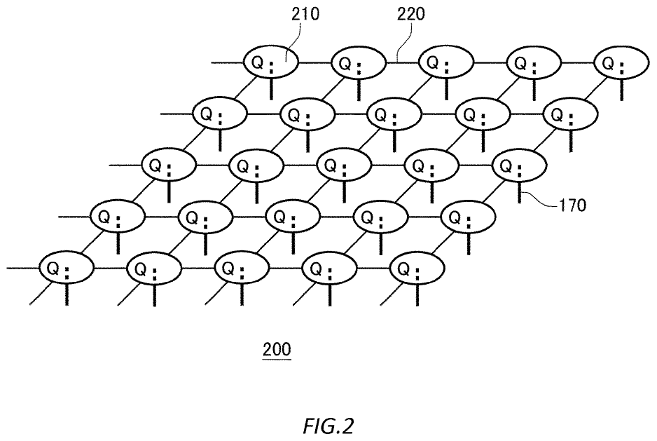

FIG. 2 schematically illustrates a qubit device 200. The qubit device 200 is an example of the electric circuit device 100. The qubit device 200 may be a superconducting qubit device. The qubit device 200 includes a qubit element 210, an in-plane connection section 220, and the connection structure 170.

The qubit element 210 may be a qubit having a Josephson junction. The qubit element 210 may be a superconducting qubit of a transmon type. The qubit device 200 of the present example includes a plurality of qubit elements 210. The plurality of qubit elements 210 may be arranged in a two-dimensional array. The plurality of adjacent qubit elements 210 may be coupled by the in-plane connection section 220.

The connection structure 170 may be a TSV connecting a top and a bottom of the substrate. The connection structure 170 may connect the plurality of qubit elements 210 arranged in the two-dimensional array to out-of-plane wirings. With the provision of the connection structure 170, it is facilitated to connect even the qubit elements 210 on an inner side of the two-dimensional array to external wirings. With this configuration, it is facilitated to accomplish a two-dimensional integration of the qubits.

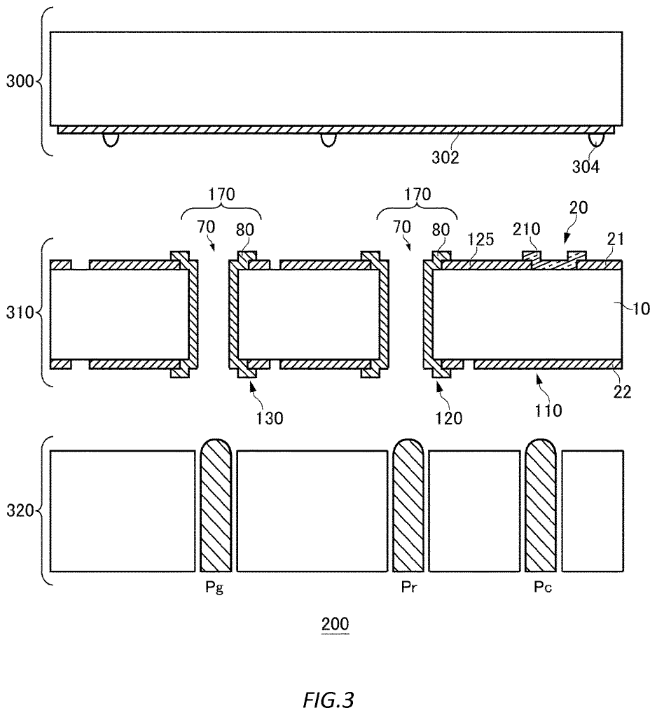

FIG. 3 illustrates an outline of a configuration of the qubit device 200. The qubit device 200 includes a cover 300, a chip 310, and a control probe layer 320. The qubit device 200 may be a quantum computer which performs information processing based on laws of quantum mechanics. The qubit device 200 of the present example executes control and readout of the qubits in a state in which the cover 300, the chip 310, and the control probe layer 320 are stacked and electrically connected. The control probe layer 320 of the present example has a control probe Pc, a readout probe Pr, and a ground probe Pg.

The cover 300 may be a flip chip cover configured to transmit and receive a signal with an outside of the qubit device 200. The cover 300 has a conductive layer 302 and a bump 304. By causing the bump 304 to be in contact with the front surface conductive layer 21, the cover 300 is electrically connected to the chip 310. A material of the conductive layer 302 may be a superconductive material.

The chip 310 includes the qubit element 210 formed on the upper surface of the substrate 10. A material of the front surface conductive layer 21 and the back surface conductive layer 22 may be a superconductive material. The chip 310 may have a control port 110, a readout port 120, and a ground port 130.

The control port 110 may be provided on the back surface 12 of the substrate 10, and electrically connected to the control probe Pc. The control probe Pc supplies a control signal for controlling the qubit of the qubit element 210 to the control port 110. In an example, the control probe Pc supplies a control signal for controlling the qubit element 210 by using a microwave at a predetermined frequency to the control port 110.

The readout port 120 may be electrically connected to the readout probe Pr. The readout port 120 may have the connection structure 170 penetrating from the front surface 11 to the back surface 12. The readout port 120 may connect a reading section 125 of the front surface 11 via the connection structure 170 to the readout probe Pr.

The reading section 125 may read a state of the qubit by being coupled to the qubit of the qubit element 210 by using a microwave. The reading section 125 may include a filter and a resonator. The filter may be a bandpass filter having a capacitor and an inductor. The resonator may be an LC resonator which is coupled to the qubit and in which a resonance frequency changes according to the state of the qubit. The readout probe Pr supplies a signal for reading the qubit of the qubit element 210 to the readout port 120.

The ground port 130 may be electrically connected to the ground probe Pg. The ground port 130 may have the connection structure 170 penetrating from the front surface 11 to the back surface 12. The ground port 130 may connect the front surface conductive layer 21 of the front surface 11 to the ground probe Pg via the connection structure 170.

The qubit device 200 of the present example can improve a wiring density by providing the connection structure 170 to the chip 310. With this configuration, it is facilitated to integrate the plurality of qubit elements 210 on the front surface 11 of the substrate 10 in the qubit device 200. In addition, with the formation of the connection structure 170, it is facilitated to reduce interference between the adjacent qubit elements 210.

Next, a fabrication method for the electric circuit device 100 will be described. As an example, processes in step S100 to step S116 will be described, but the fabrication method for the electric circuit device 100 is not limited to these processes. In addition, as an example of the fabrication method for the electric circuit device 100, a process of forming a Josephson junction may be described. However, the fabrication method for the electric circuit device 100 of the present example may be applied to a fabrication method other than the qubit device 200, such as the MEMS.

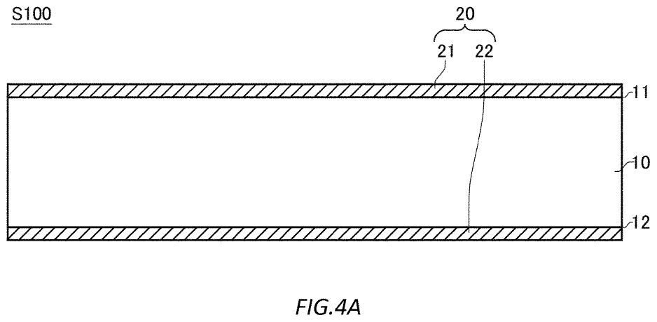

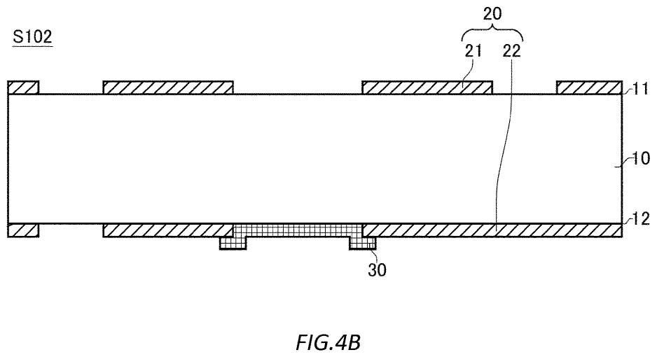

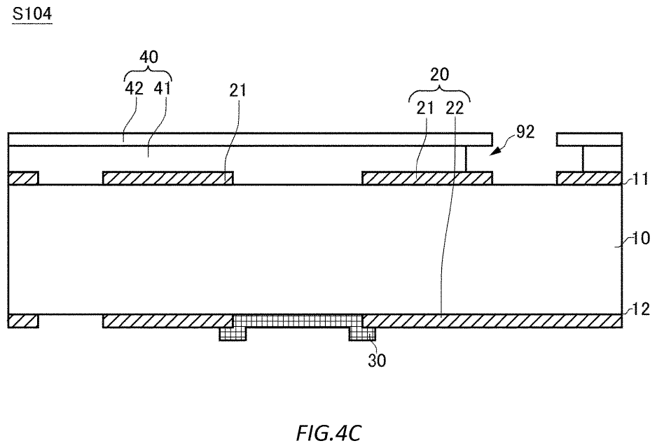

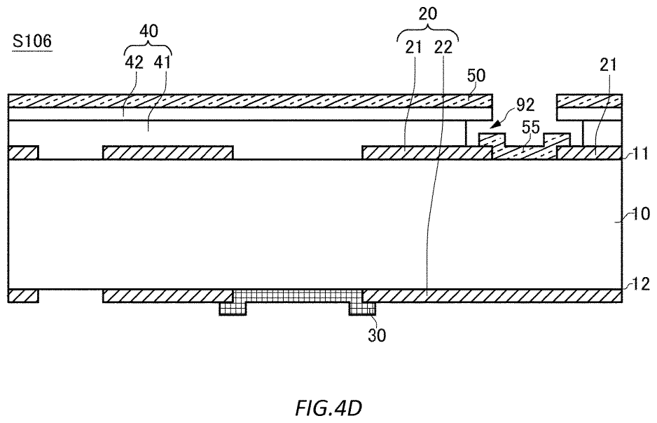

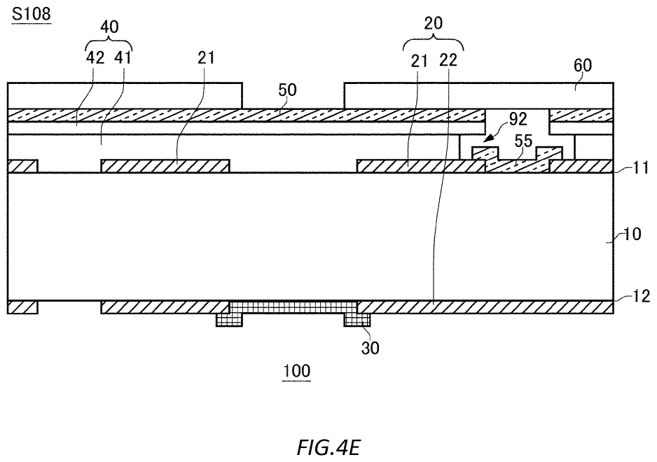

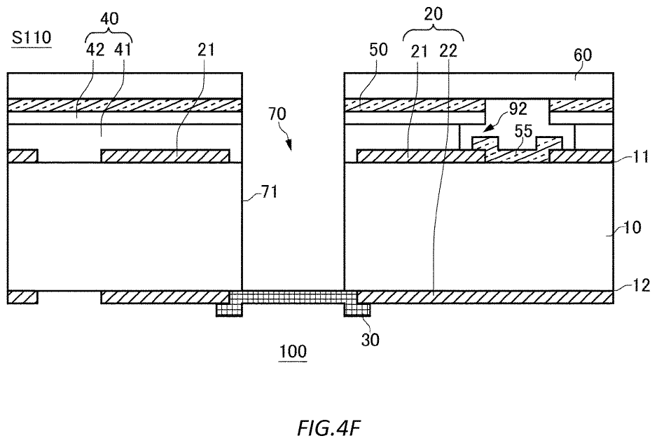

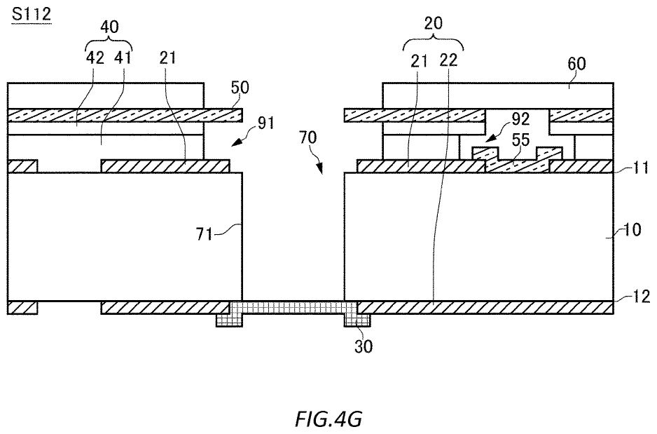

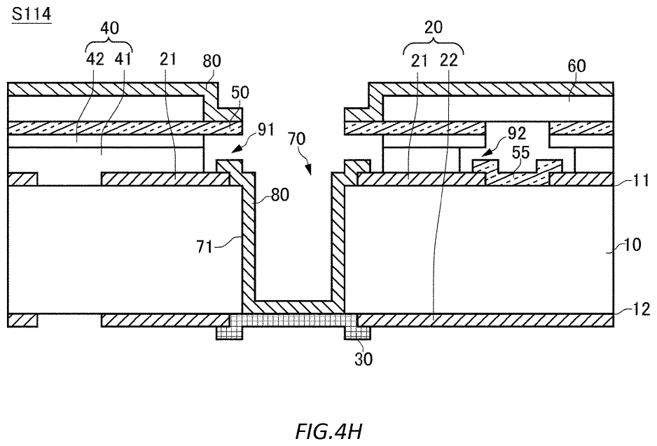

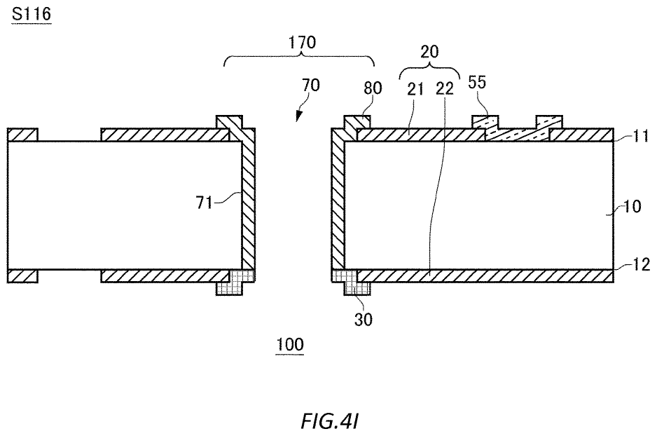

FIG. 4A is a diagram for describing the fabrication method for the electric circuit device 100. In step S100, the substrate 10 is prepared, and the conductive layer 20 is formed on the substrate 10. The substrate 10 of the present example is a high resistance silicon substrate. The substrate 10 may be cleaned before the formation of the conductive layer 20. In the substrate 10, a natural oxide film on the surface may be removed using hydrofluoric acid or the like before the formation of the conductive layer 20.

Film formation of the conductive layer 20 may be performed by any means such as a sputtering process or a vacuum deposition process. The film formation of the conductive layer 20 of the present example is performed by the sputtering process. The conductive layer 20 may contain at least one of aluminum, tantalum, niobium, niobium nitride, titanium, titanium nitride, copper, gold, silver or tungsten. In the present example, the front surface conductive layer 21 is formed on the front surface 11 of the substrate 10, and the back surface conductive layer 22 is formed on the back surface 12 of the substrate 10. One of the front surface conductive layer 21 or the back surface conductive layer 22 may be formed, or both the front surface conductive layer 21 and the back surface conductive layer 22 may be formed.

FIG. 4B is a diagram for describing the fabrication method for the electric circuit device 100. In step S102, the conductive layer 20 is patterned, and the etch stop layer 30 is formed.

The conductive layer 20 is patterned into a predetermined circuit pattern by a lithography process and an etch process. In the present example, both the front surface conductive layer 21 and the back surface conductive layer 22 are patterned. By the patterning of the front surface conductive layer 21, the resonator and the filter of the reading section 125 may be formed. In a formation process of the conductive layer 20, a circuit other than the Josephson junction may be formed.

The lithography process of the conductive layer 20 may be a UV lithography using a photoresist mask. In the present example, a positive photoresist is used, but a negative photoresist may be used. A configuration may be adopted where the photoresist is not formed in a region where the contact hole 70 is to be formed later, and the front surface conductive layer 21 and the back surface conductive layer 22 may be removed by the etch process.

The etch process of the conductive layer 20 may be dry etching, or may be wet etching. The etch process of the present example is reactive ion etching using a CF₄ plasma.

After the etch process of the conductive layer 20, the substrate 10 may be washed. A mask remaining after the etch process may be removed by an organic solvent. In an example, the substrate 10 may be washed using any remover, isopropyl alcohol (IPA), and de-ionized water.

When both the front surface conductive layer 21 and the back surface conductive layer 22 are formed, the washing process of the substrate 10 may be performed twice to wash each of the front surface 11 and the back surface 12. While one surface is treated, in order to avoid damage or contamination of another surface, a holder for spin coating protection may be used. In addition, for the heating of the photoresist, an oven may be used in which the substrate 10 can be heated while the substrate 10 is held by a holder, instead of a hot plate on which the substrate 10 is directly placed.

After the patterning process of the conductive layer 20, an etch stop layer 30 may be formed on the back surface 12. The etch stop layer 30 may be formed below the region in which the contact hole 70 is to be formed by a lithography process and an etch process. The etch stop layer 30 may be formed so as to be in contact with the back surface conductive layer 22. The etch stop layer 30 may be subjected to dry etching or may be subjected to wet etching. When the etch stop layer 30 is aluminum, an aluminum etchant may be used to perform wet etching on the etch stop layer 30. A mask remaining after the etch process may be removed by an organic solvent.

The etch stop layer 30 has a resistance to an etching plasma for forming the contact hole 70. The etch stop layer 30 may have a resistance to a fluorine ion plasma. The etch stop layer 30 may have a conductive property. A material of the etch stop layer 30 may be the same as the material of the back surface conductive layer 22, or may be a different material. The etch stop layer 30 may be a superconductor. The etch stop layer 30 may function as part of a circuit of the electric circuit device 100. The material of the etch stop layer 30 may be aluminum.

After the conductive layer 20 and the etch stop layer 30 are formed, the substrate 10 may be washed. The substrate 10 may be treated by an oxygen plasma to remove the remaining photoresist. Then, an oxide may be removed from the conductive layer 20 by a solution such as hydrofluoric acid. By cleaning the substrate 10 after the formation of the high quality conductive layer 20 and protecting the conductive layer 20 by a bottom resist layer 40 in step S104 described later, cleanliness of the conductive layer 20 can be maintained.

FIG. 4C is a diagram for describing the fabrication method for the electric circuit device 100. In step S104, the bottom resist layer 40 is formed on the conductive layer 20. In the present example, a first resist layer 41 and a second resist layer 42 are formed as the bottom resist layer 40.

The first resist layer 41 is formed over an entire surface above the substrate 10. The first resist layer 41 may be formed on the conductive layer 20. The first resist layer 41 of the present example is formed on the front surface conductive layer 21. The first resist layer 41 may be formed so to cover both the front surface conductive layer 21 and the front surface 11 of the substrate 10.

The second resist layer 42 is formed on the first resist layer 41. The second resist layer 42 is formed over an entire surface above the first resist layer 41. The second resist layer 42 may be a resist layer different from the first resist layer 41. A material of the second resist layer 42 may be different from a material of the first resist layer 41. The second resist layer 42 may have a different exposure sensitivity from an exposure sensitivity of the first resist layer 41. A thickness of the second resist layer 42 may be the same as or may be different from a thickness of the first resist layer 41.

The first resist layer 41 and the second resist layer 42 may be electron beam resists. The first resist layer 41 and the second resist layer 42 may be formed by spin coating. An overall thickness of the bottom resist layer 40 may be 0.5 μm or more and 2 μm or less. The thickness of the first resist layer 41 may be approximately 500 nm. The thickness of the second resist layer 42 may be approximately 500 nm.

After the first resist layer 41 and the second resist layer 42 are formed over the entire surface of the substrate 10, any pattern may be formed by exposing the first resist layer 41 and the second resist layer 42 to electron beam. When the electric circuit device 100 has the qubit element 210, the exposure may be performed by the electron beam according to a pattern of the Josephson junction. The bottom resist layer 40 may be exposed so as to form an opening according to a region where the Josephson junction is to be formed.

The first resist layer 41 below the second resist layer 42 may be removed to form an undercut structure 92. The undercut structure 92 is an example of a second undercut structure. In the present example, the undercut structure 92 is formed by developing the first resist layer 41 and the second resist layer 42. Each of the first resist layer 41 and the second resist layer 42 may be developed separately, or may be developed at the same time. In an example, after the second resist layer 42 is developed, the first resist layer 41 is developed. A dose amount of the electron beam may be adjusted such that the undercut structure 92 can be formed. With the formation of the undercut structure 92, clean lift-off can be accomplished around the region where the Josephson junction is to be formed.

FIG. 4D is a diagram for describing the fabrication method for the electric circuit device 100. In step S106, a cover layer 50 and a material layer 55 are formed.

The cover layer 50 may be formed on the bottom resist layer 40. The cover layer 50 may be used to form undercut structure 91 described later. The cover layer 50 may have resistance to a plasma for forming an undercut structure 91. That is, the cover layer 50 may have resistance to oxygen plasma treatment for removing the bottom resist layer 40. The cover layer 50 may contain at least one of aluminum, titanium, or chromium. The cover layer 50 may contain an oxide film of these materials.

The material layer 55 may be formed on the substrate 10. The material layer 55 may be formed below the second resist layer 42. The material layer 55 may be used for the Josephson junction. That is, when the Josephson junction is formed, the cover layer 50 can be formed without newly adding a process. The material layer 55 may contain an oxide film sandwiched between metal films. The material layer 55 may contain aluminum. The material layer 55 may contain an oxide film of these materials.

The cover layer 50 and the material layer 55 may be formed at the same time in a same process. The cover layer 50 and the material layer 55 may be a same material. That is, the cover layer 50 and the material layer 55 may have a stack structure of metal, an oxide film, and metal.

The cover layer 50 and the material layer 55 may be formed using an electron beam deposition apparatus. In the electron beam deposition apparatus, a stage on which the substrate 10 is placed may be inclinable or may be rotatable. The electron beam deposition apparatus may have an argon ion gun, or may be able to supply oxygen gas. With this configuration, the electron beam deposition apparatus can form a stack structure of metal, an oxide film, and metal.

Before the process of forming the material layer 55, a natural oxide film of the front surface conductive layer 21 may be removed. The natural oxide film of the front surface conductive layer 21 may be removed by argon ions. In an example, the natural oxide film of the front surface conductive layer 21 exposed below the second resist layer 42 is removed. With this configuration, the natural oxide film of the front surface conductive layer 21 overlapped with a contact wiring of the Josephson junction can be removed to improve a contact surface between the front surface conductive layer 21 and the material layer 55.

The Josephson junction may be formed by electron beam deposition at a different inclination angle through the opening of the bottom resist layer 40. In an example, after a first aluminum layer is formed at a predetermined inclination angle, an oxide film is formed by oxidizing the first aluminum layer in an oxygen atmosphere, and a second aluminum layer is formed at an inclination angle different from the inclination angle of the first aluminum layer. With this configuration, two aluminum layers separated by aluminum oxide can be formed. The first aluminum layer and the second aluminum layer can be formed so as to partially overlap with each other by electron beam deposition at different inclination angles through the opening of the bottom resist layer 40. For example, the inclination angle of the stage is 0 degrees or more and 45 degrees or less.

Note that according to the fabrication method for the electric circuit device 100 of the present example, not only the material layer 55 that is the Josephson junction but also a stack structure of the bottom resist layer 40 and the cover layer 50 are left without being lifted off. The stack structure of the bottom resist layer 40 and the cover layer 50 may be used to form the undercut structure 91 described later. Exposure of the conductive layer 20 to another process can be avoided due to the stack structure of the bottom resist layer 40 and the cover layer 50. Thus, the cleanliness of the conductive layer 20 can be maintained without providing an additional process. With this configuration, deterioration of a characteristic of the electric circuit device 100 can be reduced.

FIG. 4E is a diagram for describing the fabrication method for the electric circuit device 100. In step S108, a top resist layer 60 is formed on the cover layer 50.

The top resist layer 60 may be formed on the stack structure of the bottom resist layer 40 and the cover layer 50. The top resist layer 60 may be formed by spin coating. The top resist layer 60 functions as a mask for forming the contact hole 70. That is, the top resist layer 60 may have resistance to an etching plasma for forming the contact hole 70. The top resist layer 60 of the present example functions as a mask for a deep reactive ion etching (DRIE) process described later.

The top resist layer 60 may be a positive resist. A thickness of the top resist layer 60 may be 3 μm or more and 15 μm or less. The top resist layer 60 formed in the region where the contact hole 70 is to be formed may be removed by any lithography process and development process. The lithography process may be a photolithography process. By developing the top resist layer 60, the cover layer 50 may be exposed. The resist remaining on the surface of the exposed cover layer 50 may be removed by oxygen plasma treatment.

FIG. 4F is a diagram for describing the fabrication method for the electric circuit device 100. In step S110, the contact hole 70 is formed in the substrate 10 while the top resist layer 60 is used as a mask. The contact hole 70 of the present example may be formed after the conductive layer 20 is formed. While the top resist layer 60 is used as a common mask, the cover layer 50, the bottom resist layer 40, and the substrate 10 are etched.

Wet etching or dry etching may be performed on the cover layer 50 while the top resist layer 60 is used as a mask. In the present example, wet etching is performed on the cover layer 50. The material layer 55 may be covered with the top resist layer 60 so as not to be etched. When the cover layer 50 is aluminum, an aluminum etchant may be used to perform wet etching on the cover layer 50. After the cover layer 50 is etched, the substrate 10 may be input to a DRIE apparatus.

The bottom resist layer 40 may be removed by a method different from the method for the cover layer 50. The bottom resist layer 40 may be removed in an apparatus which forms the contact hole 70. The bottom resist layer 40 of the present example is removed by an oxygen plasma. By removing the bottom resist layer 40, part of the front surface 11 of the substrate 10 may be exposed. The bottom resist layer 40 may be removed by dry etching. The first resist layer 41 and the second resist layer 42 may be removed by a same method. The bottom resist layer 40 of the present example is removed by the DRIE apparatus configured to etch the substrate 10.

In the substrate 10, the bottom resist layer 40 and the cover layer 50 may be etched by different methods. In the substrate 10 of the present example, etching is performed by the DRIE apparatus using a Bosch process in which an etch process and a passivation process are repeated. An SF₆ plasma may be used as a gas for the etch process, and a C₄F₈ plasma may be used as a gas for the passivation process. By etching the substrate 10 by using the Bosch process, penetration may be achieved from the front surface 11 to the back surface 12 of the substrate 10. It is noted however that in the substrate 10, the contact hole 70 may be formed by performing etching once. By etching the substrate 10 above the etch stop layer 30, an upper surface of the etch stop layer 30 may be exposed.

Note that irregularities may be formed on the sidewall 71 when the contact hole 70 is formed by using the Bosch process. After an upper surface of the etch stop layer 30 is exposed and before the contact metal layer 80 is to be formed, the sidewall 71 of the contact hole 70 may be etched. In an example, after the upper surface of the etch stop layer 30 is exposed, a single-shot etch process is performed to smooth the irregularities of the sidewall 71. A mixture of SF₆ and C₄F₈ plasma may be used as a gas for the etch process. By smoothing the irregularities of the sidewall 71 of the contact hole 70, it is facilitated to uniformly form the contact metal layer 80.

FIG. 4G is a diagram for describing the fabrication method for the electric circuit device 100. In step S112, the undercut structure 91 is formed. The undercut structure 91 is an example of a first undercut structure.

The undercut structure 91 is formed by etching the bottom resist layer 40 below the cover layer 50. The bottom resist layer 40 is etched below the cover layer 50 until the conductive layer 20 is exposed. In the present example, the bottom resist layer 40 is etched until the front surface conductive layer 21 below the cover layer 50 is exposed.

The undercut structure 91 may be formed by an oxygen plasma process. By forming the undercut structure 91 in which the cover layer 50 overhangs, while the conductive layer 20 is kept in a clean state, the contact metal layer 80 can be formed to be electrically connected to the conductive layer 20. In addition, by forming the undercut structure 91, clean lift-off of the contact metal layer 80 around the contact hole 70 can be accomplished.

Before the contact metal layer 80 is to be formed, the passivation layer formed on the sidewall 71 of the contact hole 70 by the formation process of the contact hole 70 may be removed. The passivation layer may be removed by an oxygen plasma. The passivation layer on the sidewall of the sidewall 71 may be removed by oxygen plasma treatment for forming the undercut structure 91. That is, without adding a new process, the undercut structure 91 can be formed by using removal treatment for the passivation layer of the contact hole 70 in common. A higher quality superconducting circuit can be provided by removing the passivation layer remaining on the sidewall 71 of the contact hole 70.

Since the material layer 55 of the present example is protected by the top resist layer 60 and/or the undercut structure 92, damage by the oxygen plasma treatment can be avoided. With this configuration, it is possible to form the high quality Josephson junction.

FIG. 4H is a diagram for describing the fabrication method for the electric circuit device 100. In step S114, the contact metal layer 80 is formed. After the undercut structure 91 is formed, the substrate 10 may be inserted into the electron beam deposition apparatus configured to form the contact metal layer 80.

After the undercut structure 91 is formed, the contact metal layer 80 is formed on the sidewall 71 of the contact hole 70 and the front surface 11 of the substrate 10. The contact metal layer 80 may be formed so as to be overlapped with the front surface conductive layer 21 exposed below the cover layer 50. The contact metal layer 80 may also be formed on an upper surface in an exposed region of the etch stop layer 30. For the contact metal layer 80, any material may be deposited by electron beam deposition. The contact metal layer 80 may be formed by the electron beam deposition apparatus. The contact metal layer 80 may also be formed on the cover layer 50 and the top resist layer 60.

The stage on which the substrate 10 is placed in the electron beam deposition apparatus may be inclinable and may be rotatable. By adjusting the inclination angle and the rotation angle of the stage, it is facilitated to form the contact metal layer 80 over an entire surface of the sidewall 71 of the contact hole 70. In addition, by adjusting the inclination angle of the stage, it is facilitated to form the contact metal layer 80 so as to be overlapped with the front surface conductive layer 21 of the undercut structure 91. The contact metal layer 80 may be formed while at least one of the inclination angle or the rotation angle of the stage is changed.

Before the contact metal layer 80 is formed, a natural oxide film formed on the sidewall 71 of the contact hole 70 may be removed. The natural oxide film of the sidewall 71 may be removed by spattering argon ions in the electron beam deposition apparatus configured to form the contact metal layer 80. Argon ions may be emitted while at least one of the inclination angle or the rotation angle of the stage is changed. The inclination angle and the rotation angle of the stage may be the same as those angles during the formation of the contact metal layer 80. In an example, the inclination angle of the stage is 0 degrees or more and 45 degrees or less.

Note that the removal process of the natural oxide film and the formation process of the contact metal layer 80 may be executed once in the stated order, or may be executed repeatedly. In an example, after all the removal process for the natural oxide film is completed while the stage is adjusted, the stage is adjusted again to form the contact metal layer 80. In addition, after the stage is adjusted and the natural oxide film is removed to form the contact metal layer 80, the stage may be adjusted again and the natural oxide film may be removed to form the contact metal layer 80.

According to the fabrication method of the present example, before the contact metal layer 80 is formed, by forming the undercut structure 91 by way of the stack structure of the bottom resist layer 40 and the cover layer 50, clean lift-off of the contact metal layer 80 can be accomplished. With this configuration, highly reliable electric connection between the back surface conductive layer 22 and the contact metal layer 80 can be accomplished.

FIG. 4I is a diagram for describing the fabrication method for the electric circuit device 100. In step S116, part of the etch stop layer 30 is removed. In the present example, part of the contact metal layer 80 is also removed.

Part of the etch stop layer 30 may be removed by ultrasonic treatment in a state in which the substrate 10 is put in a remover. Film-like part of the etch stop layer 30 supported by the sidewall 71 of the contact hole 70 out of the etch stop layer 30 may be removed. It is noted however that part of the etch stop layer 30 which is to be connected to the contact metal layer 80 may be left without being removed. Part of the etch stop layer 30 which connects the contact metal layer 80 and the back surface conductive layer 22 may be left.

Part of the contact metal layer 80 may be removed in a same process as the etch stop layer 30. In the present example, part of the contact metal layer 80 which is formed on the upper surface of the etch stop layer 30 is removed. The contact metal layer 80 provided to the sidewall 71 and above the substrate 10 may be left without being removed.

In the description of the fabrication method of the present example, the specific material and chemical agent have been exemplified, but the fabrication method for the electric circuit device 100 is not limited to this. As long as an aim of the present example is achieved, other materials and chemical agents may be used. The fabrication method of the present example may also be applied to any electric circuit device 100 such as the MEMS having the contact hole 70 in the substrate 10. In addition, the order of execution of the respective steps in the fabrication method for the electric circuit device 100 is also not limited to those described above. As an example, after forming a material layer 55 including a Josephson junction, the substrate 10 may be cleaned, and then the bottom resist layer 40, the cover layer 50, and the top resist layer 60 may be sequentially formed. In this variation as well, the above-described step of forming the contact hole 70 and the step of forming the contact metal layer 80 may be similarly performed.

Herein, if the connection structure 170 is formed prior to the conductive layer 20, formation of a uniform resist on the substrate 10 may become difficult. If uniformity of a resist film thickness is impaired, fabrication fluctuation of the conductive layer 20 occurs, and a characteristic in a plane may fluctuate. According to the fabrication method of the present example, since the connection structure 170 is formed after the conductive layer 20 and the material layer 55 are formed, the uniform qubit elements 210 can be provided on the substrate 10. By providing the uniform qubit elements 210 on the substrate 10, Josephson energy of the qubits, control on frequencies of the qubits, and the like can be uniformized to improve the characteristic of the qubit device 200.

On the other hand, if the connection structure 170 is formed after the conductive layer 20 is formed, an occasion to wash the substrate 10 after the conductive layer 20 and the material layer 55 are formed is limited, and it may be difficult to remove contamination in a subsequent process. According to the fabrication method of the present example, by forming the contact hole 70 in a state in which the stack structure of the bottom resist layer 40 and the cover layer 50 is left, the conductive layer 20 and the material layer 55 can be protected.

According to the fabrication method of the present example, even when the connection structure 170 is formed, the characteristic of the electric circuit device 100 can be improved while throughput is improved. In addition, according to the fabrication method of the present example, by improving a quality of a superconductive film, deterioration of coherence time of the qubit can be reduced, and the higher performance qubit device 200 can be accomplished.

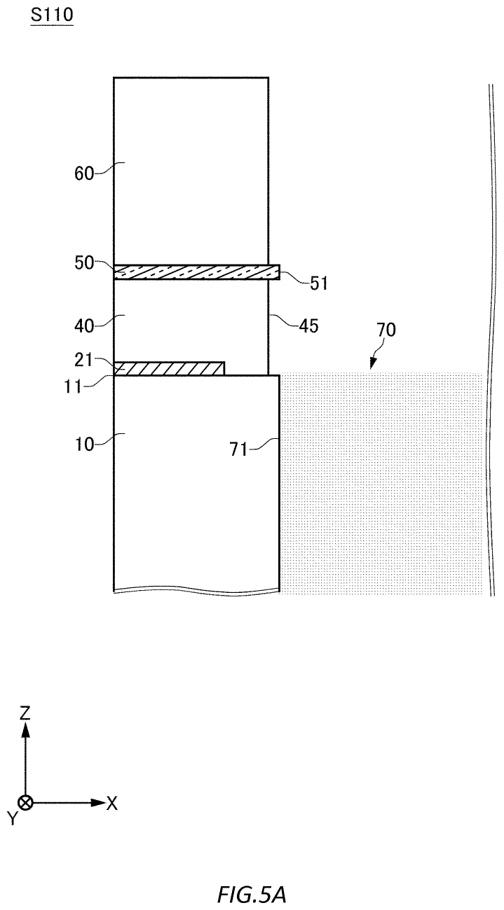

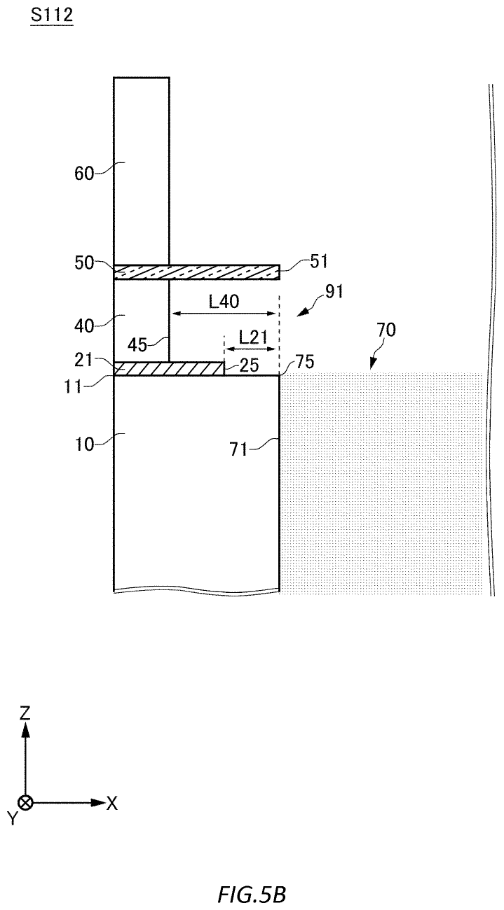

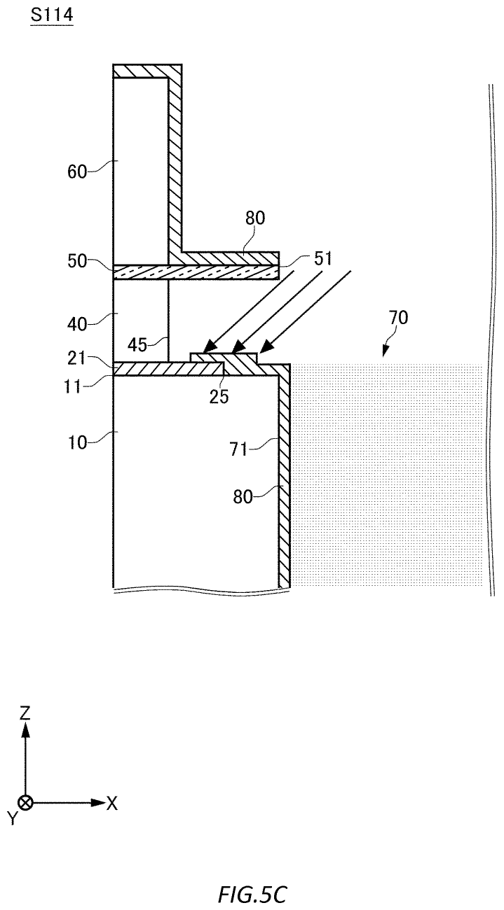

FIG. 5A is an example of an enlarged view of an area near the contact hole 70. The present drawing illustrates an enlarged view of the area near the contact hole 70 formed in step S110 of FIG. 4F. In step S110, the contact hole 70 is formed, but the undercut structure 91 is not formed. It is noted however that side etching may be further performed on a sidewall 45 of the bottom resist layer 40 as compared with a sidewall 51 of the cover layer 50. The front surface conductive layer 21 is covered with the bottom resist layer 40 without being exposed.

FIG. 5B is an example of the enlarged view of the area near the contact hole 70. The present drawing illustrates an enlarged view of the area near the contact hole 70 after the undercut structure 91 is formed in step S112 of FIG. 4G.

A distance L21 is a distance from an upper end 75 of the sidewall 71 to an exposed end 25 of the front surface conductive layer 21. The distance L21 may be a shortest distance from the upper end 75 to the end 25. The distance L21 may be a distance in a direction (for example, an X axis direction) parallel to the front surface 11 of the substrate 10. The distance L21 may be a size with which the front surface conductive layer 21 can be exposed by removing the bottom resist layer 40. The distance L21 may be a size with which connection to the contact metal layer 80 is allowed below the cover layer 50. The distance L21 may be 0 μm or more and 1.5 μm or less.

A distance L40 is a distance from the sidewall 71 to the sidewall 45 of the bottom resist layer 40 in a direction orthogonal to the depth direction of the substrate 10. The distance L40 is larger than the distance L21. The distance L40 may be 1 μm or more and 3 μm or less. The distance L40 changes according to a condition of the oxygen plasma treatment for removing the bottom resist layer 40. The distance L40 may change according to a thickness of the bottom resist layer 40. The thickness of the bottom resist layer 40 may be smaller than the thickness of the top resist layer 60.

FIG. 5C is an example of the enlarged view of the area near the contact hole 70. The present drawing illustrates an enlarged view of the area near the contact hole 70 after the contact metal layer 80 is formed in step S114 of FIG. 4H.

The contact metal layer 80 may be formed so as to extend along the substrate 10 from the sidewall 71 of the contact hole 70 to the conductive layer 20. The contact metal layer 80 may be formed to be overlapped with the front surface conductive layer 21 in the front surface 11. The contact metal layer 80 may be formed so as to be overlapped with the front surface conductive layer 21 beyond the end 25 of the front surface conductive layer 21. The contact metal layer 80 of the present example is formed to be spaced away from the sidewall 45 of the bottom resist layer 40.

The contact metal layer 80 may be deposited while the inclination angle of the stage on which the substrate 10 is place is changed. The inclination angle of the stage on which the substrate 10 is placed during the formation of the contact metal layer 80 may be adjusted such that the contact metal layer 80 can be electrically connected to the front surface conductive layer 21. The inclination angle of the stage may be decided according to the thickness of the bottom resist layer 40, a position of the end 25 of the front surface conductive layer 21, a position of the sidewall 51 of the cover layer 50, and the like. For the sidewall 71 of the contact hole 70 and the front surface 11 of the substrate 10, the contact metal layer 80 may be deposited at different inclination angles of the stage. The inclination angle of the stage may be 0 degrees or more and 45 degrees or less. In addition, by rotating the stage on which the substrate 10 is placed, the contact metal layer 80 may be uniformly formed irrespective of the position of the sidewall 71.

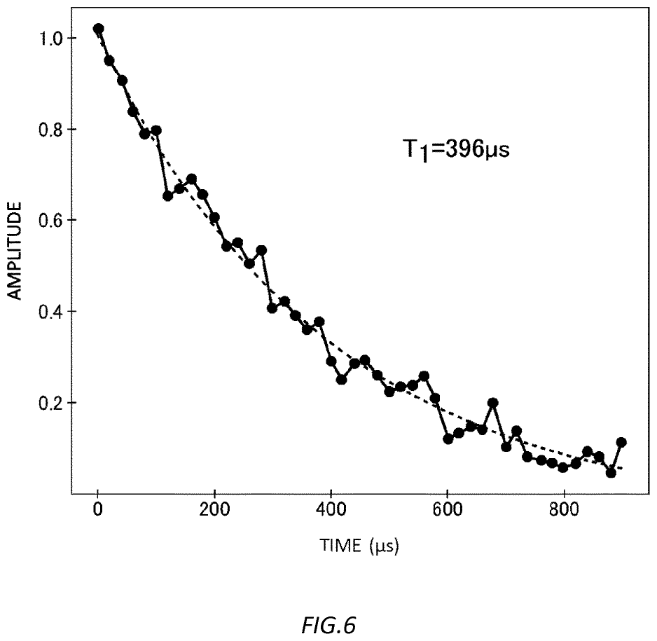

FIG. 6 illustrates an example of a relaxation time T₁ of the qubit device 200. The relaxation time T₁ is a period of time for the qubit controlled to be in an excited state to transition into a ground state. A horizontal axis represents a time (μs) from a time when the qubit is controlled to be in the excited state until measurement is performed. A vertical axis represents a measured amplitude. A relaxation curve indicating an exponential attenuation based on a measurement result at each time. A time constant of the relaxation curve becomes the relaxation time T₁. The relaxation time T₁ of the qubit device 200 of the present example is 396 μs.

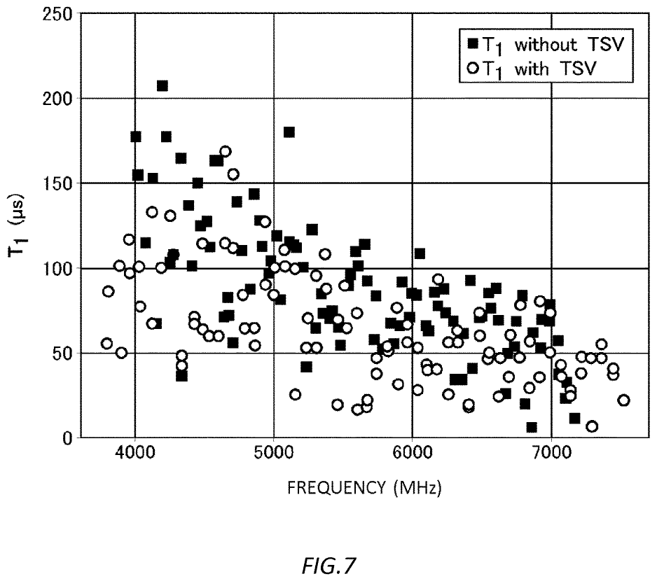

FIG. 7 illustrates an experimental result of the relaxation time T₁. A vertical axis represents the relaxation time T₁ (μs), and a horizontal axis represents a frequency (MHz) of a measurement signal. A rectangular plot represents the relaxation time T₁ of the qubit device which does not have a TSV. A circular plot represents the relaxation time T₁ of the qubit device 200 which has a TSV formed by using the fabrication method of the invention of the present application. From a result of the present example, the qubit device 200 can obtain the equivalent relaxation time T₁ even as compared with the qubit device in which the TSV is not formed.

While the present invention has been described by way of the embodiments, the technical scope of the present invention is not limited to the above described embodiments. It is apparent to persons skilled in the art that various alterations or improvements can be made to the above described embodiments. It is also apparent from the description of the claims that embodiments added with such alterations or improvements can be included in the technical scope of the present invention.

The operations, procedures, steps, and stages of each process performed by an apparatus, system, program, and method illustrated in the claims, embodiments, or diagrams can be performed in any order as long as the order is not indicated by “prior to,” “before,” or the like and as long as the outputted from a previous process is not used in a later process. Even if the operation flow is described by using phrases such as “first” or “next” in the scope of the claims, specification, or drawings, it does not necessarily mean that the process must be performed in this order.

### EXPLANATION OF REFERENCE NUMBERS

10: substrate; 11: front surface; 12: back surface; 20: conductive layer; 21: front surface conductive layer; 22: back surface conductive layer; 25: end; 30: etch stop layer; 40: bottom resist layer; 41: first resist layer; 42: second resist layer; 45: sidewall; 50: cover layer; 51: sidewall; 55: material layer; 60: top resist layer; 70: contact hole; 71: sidewall; 72: bottom surface; 75: upper end; 80: contact metal layer; 91: undercut structure; 92: undercut structure; 100: electric circuit device; 110: control port; 120: readout port; 125: reading section; 130: ground port; 170: connection structure; 200: qubit device; 210: qubit element; 220: in-plane connection section; 300: cover; 302: conductive layer; 304: bump; 310: chip; 320: control probe layer.

What is claimed is:

1. A fabrication method for an electric circuit device, the fabrication method comprising:
forming a conductive layer on a substrate;
forming a bottom resist layer on the conductive layer;
forming a cover layer on the bottom resist layer;
forming a top resist layer on the cover layer;
forming a contact hole in the substrate by using the top resist layer as a mask;
forming a first undercut structure by etching the bottom resist layer below the cover layer; and
forming a contact metal layer on a sidewall of the contact hole and above a front surface of the substrate after the first undercut structure is formed.

2. The fabrication method for the electric circuit device according to claim 1, wherein
the forming the contact metal layer includes forming the contact metal layer so as to extend along the substrate from the sidewall of the contact hole to the conductive layer.

3. The fabrication method for the electric circuit device according to claim 1, wherein
the forming the first undercut structure includes etching the bottom resist layer until the conductive layer is exposed below the cover layer.

4. The fabrication method for the electric circuit device according to claim 2, wherein
the forming the first undercut structure includes etching the bottom resist layer until the conductive layer is exposed below the cover layer.

5. The fabrication method for the electric circuit device according to claim 3, wherein
a distance from an upper end of the sidewall of the contact hole to an exposed end of the conductive layer is 0 μm or more and 1.5 μm or less.

6. The fabrication method for the electric circuit device according to claim 4, wherein
a distance from an upper end of the sidewall of the contact hole to an exposed end of the conductive layer is 0 μm or more and 1.5 μm or less.

7. The fabrication method for the electric circuit device according to claim 1, wherein
the conductive layer contains at least one of aluminum, tantalum, niobium, niobium nitride, titanium, titanium nitride, copper, gold, silver or tungsten.

8. The fabrication method for the electric circuit device according to claim 2, wherein
the conductive layer contains at least one of aluminum, tantalum, niobium, niobium nitride, titanium, titanium nitride, copper, gold, silver or tungsten.

9. The fabrication method for the electric circuit device according to claim 3, wherein
the conductive layer contains at least one of aluminum, tantalum, niobium, niobium nitride, titanium, titanium nitride, copper, gold, silver or tungsten.

10. The fabrication method for the electric circuit device according to claim 1, wherein
the contact metal layer contains at least one of aluminum, tantalum, niobium, niobium nitride, titanium, titanium nitride, copper, gold, silver or tungsten.

11. The fabrication method for the electric circuit device according to claim 1, wherein
the forming the contact metal layer includes changing an inclination angle of a stage on which the substrate is placed, and depositing the contact metal layer on the sidewall of the contact hole and above the front surface of the substrate.

12. The fabrication method for the electric circuit device according to claim 1, wherein
the forming the conductive layer includes forming a back surface conductive layer on a back surface of the substrate, and
the fabrication method comprises forming a conductive etch stop layer so as to be in contact with the back surface conductive layer.

13. The fabrication method for the electric circuit device according to claim 12, wherein
the forming the contact hole includes exposing an upper surface of the etch stop layer by etching the substrate above the etch stop layer, and
the forming the contact metal layer includes forming the contact metal layer on the upper surface in an exposed region of the etch stop layer.

14. The fabrication method for the electric circuit device according to claim 13, comprising:
after the exposing the upper surface of the etch stop layer and before the forming the contact metal layer, etching the sidewall of the contact hole.

15. The fabrication method for the electric circuit device according to claim 13, comprising:
removing the etch stop layer while part of the etch stop layer which connects the contact metal layer and the back surface conductive layer is left.

16. The fabrication method for the electric circuit device according to claim 1, wherein
the forming the bottom resist layer includes:
forming a first resist layer on the conductive layer; and
forming, on the first resist layer, a second resist layer that is different from the first resist layer.

17. The fabrication method for the electric circuit device according to claim 16, comprising:
forming a second undercut structure by etching the first resist layer below the second resist layer, wherein
the forming the cover layer includes forming, below the second resist layer, a material layer of a same material as a material of the cover layer.

18. The fabrication method for the electric circuit device according to claim 17, comprising:
forming a Josephson junction by using the material layer.

19. The fabrication method for the electric circuit device according to claim 18, wherein
the cover layer contains aluminum.

20. The fabrication method for the electric circuit device according to claim 1, wherein
the electric circuit device is a superconducting qubit device.
